(19) United States
(12) Patent Application Publication
(10) Pub. No.: US 2025/0140723 A1
(43) Pub. Date: May 1, 2025

(54) SEMICONDUCTOR PACKAGE AND METHOD OF MANUFACTURING A SEMICONDUCTOR PACKAGE

(71) Applicant: SAMSUNG ELECTRONICS CO., LTD., Suwon-si (KR)

(72) Inventors: Jihoon KIM, Suwon-si (KR); Jinkyeong SEOL, Suwon-si (KR); Raeyoung KANG, Suwon-si (KR); Minki KIM, Suwon-si (KR); Hyeonkyu HA, Suwon-si (KR)

(73) Assignee: SAMSUNG ELECTRONICS CO., LTD., Suwon-si (KR)

(21) Appl. No.: 18/671,443

(22) Filed: May 22, 2024

(30) Foreign Application Priority Data
Oct. 26, 2023 (KR) 10-2023-0144560

(51) Int. Cl. H01L 23/00; H01L 23/48; H01L 25/065; H10B 80/00

(52) U.S. Cl. CPC H01L 24/06; H01L 23/481; H01L 24/05; H01L 24/08; H01L 24/81; H01L 25/0657; H01L 2224/05124; H01L 2224/05147; H01L 2224/05647; H01L 2224/06051; H01L 2224/08145; H01L 2224/81379; H10B 80/00

(57) ABSTRACT

A semiconductor package includes a plurality of semiconductor chips bonded to each other through direct bonding, the plurality of semiconductor chips including a first semiconductor chip and a second semiconductor chip. The first semiconductor chip including: a front insulating layer bonded to a back insulating layer of the second semiconductor chip; a front pad surrounded by the front insulating layer; a device layer on a back surface of the front insulating layer and including an interconnection structure electrically connected to the front pad; a conductive pattern between the interconnection structure and the front pad; and a support insulating layer between the device layer and the front insulating layer and surrounding the conductive pattern, wherein a gap is between a first side surface of the support insulating layer and a second side surface of the conductive pattern that faces the first side surface.

### CROSS-REFERENCE TO RELATED APPLICATION(S)

This application claims the benefit under 35 USC 119 (a) of Korean Patent Application No. 10-2023-0144560, filed on Oct. 26, 2023, in the Korean Intellectual Property Office, the entire disclosure of which is incorporated herein by reference for all purposes.

### BACKGROUND

### 1. Technical Field

Embodiments of the present disclosure relate to a semiconductor package and a method of manufacturing a semiconductor package.

### 2. Brief Description of Related Art

According to the trend for miniaturization and higher performance of semiconductor packages, the development of system-in-package (SiP) technology in which a plurality of semiconductor chips performing different functions are embedded in a single package is required. To form fine wirings connecting semiconductor chips within a package, a technology is being used to form a Through Silicon Via (TSV) and bond semiconductor chips to each other through bonding pads.

### SUMMARY

Example embodiments of the present disclosure provide a semiconductor package and a method of manufacturing a semiconductor package with improved electrical characteristics and/or reliability of a front surface of a semiconductor chip.

According to embodiments of the present discourse, a semiconductor package is provided and includes a plurality of semiconductor chips bonded to each other through direct bonding, the plurality of semiconductor chips including a first semiconductor chip and a second semiconductor chip. The first semiconductor chip including: a front insulating layer bonded to a back insulating layer of the second semiconductor chip; a front pad surrounded by the front insulating layer; a device layer on a back surface of the front insulating layer and including an interconnection structure electrically connected to the front pad; a conductive pattern between the interconnection structure and the front pad; and a support insulating layer between the device layer and the front insulating layer and surrounding the conductive pattern, wherein a gap is between a first side surface of the support insulating layer and a second side surface of the conductive pattern that faces the first side surface.

According to embodiments of the present discourse, a semiconductor package is provided and includes a semiconductor chip including: a front insulating layer; a front pad surrounded by the front insulating layer; a device layer on a back surface of the front insulating layer and including an interconnection structure electrically connected to the front pad; a conductive pattern between the interconnection structure and the front pad; a support insulating layer between the device layer and the front insulating layer and surrounding the conductive pattern; a semiconductor substrate on a back surface of the device layer; a through-electrode penetrating through the semiconductor substrate; and a back insulating layer on a back surface of the semiconductor substrate, wherein at least one from among a first side surface of the support insulating layer and a second side surface of the conductive pattern that faces the first side surface is curved more than each of a third side surface of the front insulating layer and a fourth side surface of the front pad that faces the third side surface.

According to embodiments of the present disclosure, a method of manufacturing a semiconductor package and includes: forming a conductive pattern on a front surface of a device layer of a first semiconductor chip; disposing an insulating material on the front surface of the device layer; annealing and cooling a combination portion of the conductive pattern and the insulating material; forming a support insulating layer by flattening the insulating material; forming a front pad and a front insulating layer on a front surface of the conductive pattern and a front surface of the support insulating layer; and direct bonding the front insulating layer of the first semiconductor chip to a back insulating layer of a second semiconductor chip.

### BRIEF DESCRIPTION OF DRAWINGS

The above and other aspects, features, and advantages of example embodiments of the present disclosure will be more clearly understood from the following detailed description, taken in conjunction with the accompanying drawings, in which:

FIG. 1 is a cross-sectional view illustrating a semiconductor package according to an example embodiment;

FIG. 2A is a plan view illustrating a semiconductor package and a conductive pattern according to an example embodiment;

FIG. 2B is an enlarged view of a portion B of the semiconductor package of FIG. 1;

FIGS. 3A to 5D are cross-sectional views illustrating a method of manufacturing a semiconductor package according to an example embodiment; and

FIGS. 6A to 7B are enlarged views of a semiconductor package according to an example embodiment.

### DETAILED DESCRIPTION

The below description refers to the accompanying drawings, which illustrate, by way of example, non-limiting example embodiments of the present disclosure. These example embodiments are described in sufficient detail to enable those skilled in the art to practice embodiments of the present disclosure. It should be understood that the various embodiments are different from one another but are not necessarily mutually exclusive. For example, specific shapes, structures and characteristics described herein with respect to one embodiment may be implemented in other embodiments without departing from the spirit and scope of the present disclosure. Additionally, it should be understood that the location or arrangement of individual components within each described embodiment may be changed without departing from the spirit and scope of the present disclosure. Accordingly, the detailed description below is not intended to be taken in a limiting sense. Similar reference numbers in the drawings refer to identical or similar components and/or functions across various aspects.

It will be understood that when an element is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements present.

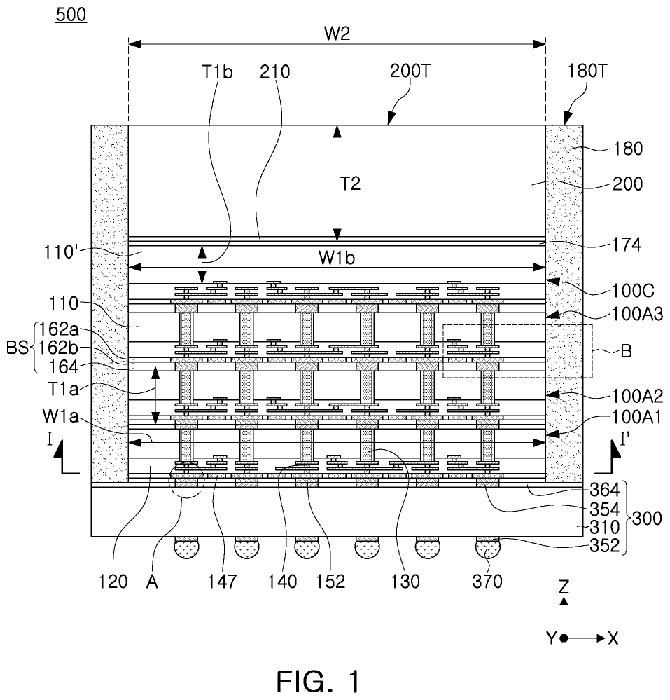

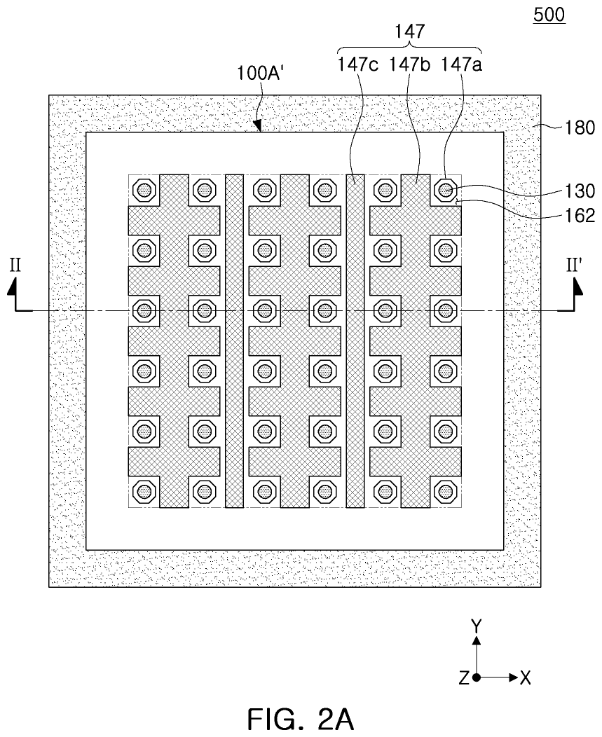

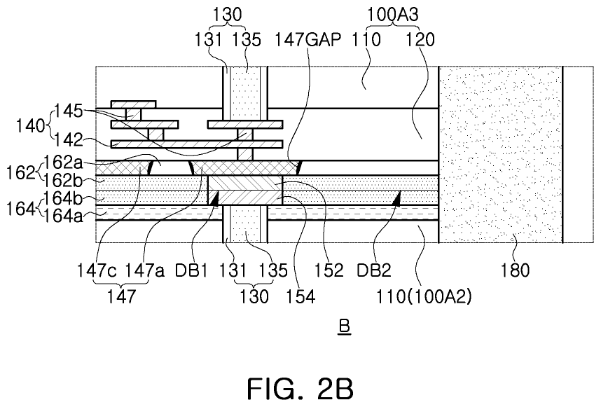

FIG. 1 illustrates an X-Z cross section cut from II to II′ in FIG. 2A, FIG. 2A illustrates an X-Y cross-section cut from I to I′ in FIG. 1, and FIG. 2B is an enlarged view of a portion (B) of FIG. 1.

Referring to FIGS. 1, 2A, and 2B, a semiconductor package 500 according to an example embodiment may include at least one of a plurality of semiconductor chips (e.g., semiconductor chips 100A1, 100A2, 100A3, and 100C). Each of the plurality of semiconductor chips (e.g., semiconductor chips 100A1, 100A2, 100A3, and 100C) may include a front insulating layer 162b, a front pad 152, a device layer 120, a semiconductor substrate 110 or a semiconductor substrate 110′), a conductive pattern 147, and a support insulating layer 162a. Each of the plurality of semiconductor chips (e.g., semiconductor chips 100A1, 100A2, 100A3, and 100C) may include a through-electrode 130, a back insulating layer 164, and a back pad 154. FIG. 1 illustrates a structure in which the number of semiconductor chips (e.g., semiconductor chips 100A1, 100A2, 100A3, and 100C) is four, but the number of semiconductor chips is not particularly limited.

The plurality of semiconductor chips (e.g., semiconductor chips 100A1, 100A2, 100A3, and 100C) may be memory chips. For example, the memory chip may be a volatile memory chip such as a Dynamic Random Access Memory (DRAM) or a Static Random Access Memory (SRAM), or may be a non-volatile memory chip such as a Phase-change Random Access Memory (PRAM), a Magnetoresistive Random Access Memory (MRAM), a Ferroelectric Random Access Memory (FeRAM) or a Resistive Random Access Memory (RRAM). Alternatively, some of the plurality of semiconductor chips (e.g., semiconductor chips 100A1, 100A2, 100A3, and 100C) may be memory chips and others may be logic chips. The logic chip may be, for example, a microprocessor, analog element, or digital signal processor, and may control the operation of memory chips. For example, a combination of the plurality of semiconductor chips (e.g., semiconductor chips 100A1, 100A2, 100A3, and 100C) may be a High Bandwidth Memory (HBM) DRAM.

The semiconductor substrate 110 and the semiconductor substrate 110′ may include a semiconductor such as silicon. For example, the semiconductor substrate 110 may include various impurity regions for individual devices and a device isolation structure such as a shallow trench isolation (STI) structure. The semiconductor is not limited to silicon and may include at least one from among germanium, silicon carbide (SiC), gallium arsenide (GaAs), indium arsenide (InAs), and indium phosphide (InP). For example, the device may include a Planar Metal Oxide Semiconductor FET (MOSFET), a FinFET of which an active region has a fin structure, a Multi Bridge Channel FET (MBCFET™) or a Gate-All-Around transistor including a plurality of channels stacked vertically on the active region, or a Vertical FET (VFET), but embodiments of the present disclosure are not limited thereto.

Each of the through-electrodes 130 may have a pillar structure penetrating through the semiconductor substrate 110. The through-electrodes 130 may not penetrate through the semiconductor substrate 110′. The upper end of the through-electrode 130 may be connected to the back pad 154, and the lower end may be electrically connected to the front pad 152 through an interconnection structure 140. The through-electrode 130 may include a via plug 135 and an insulating liner 131 surrounding the via plug 135. The insulating liner 131 may electrically separate the via plug 135 from the semiconductor substrate 110.

The device layer 120 may include an interconnection structure 140 connected to a plurality of individual devices formed on the front (lower) surface of the semiconductor substrate 110 and the semiconductor substrate 110′. The interconnection structure 140 may include an interconnection layer 142 and an interconnection via 145. For example, the interconnection structure 140 may have a structure in which a plurality of interconnection layers 142 are stacked in the Z direction, and may include a plurality of interconnection vias 145 that electrically connect the plurality of interconnection layers 142 in the Z direction. The interconnection structure 140 may be electrically connected to the front pad 152 disposed below the device layer 120. The interconnection layer 142 and the interconnection via 145 may include at least one from among copper (Cu), copper alloy, aluminum (Al), and aluminum alloy. The metal material is not limited thereto, and may be implemented as at least one from among nickel (Ni), gold (Au), cobalt (Co), tantalum (Ta), tellurium (Te), titanium (Ti), tungsten (W) or alloys thereof (for example, TiN, TaN). A space in the device layer 120 where the interconnection structure 140 is not disposed may be filled with an insulating layer. For example, the insulating layer may include at least one from among silicon oxide (SiO), silicon nitride (SiN), silicon oxynitride (SiON), silicon oxycarbide (SiOC), and silicon carbonitride (SiCN).

The front pad 152 may be arranged on the front (lower) surface of each of the plurality of semiconductor chips (e.g., the semiconductor chips 100A1, 100A2, 100A3, and 100C), and electrical paths to the outside of each of the plurality of semiconductor chips (e.g., the semiconductor chips 100A1, 100A2, 100A3, and 100C) may be provided. The exterior of each of the semiconductor chips 100A2, 100A3, and 100C may be the back pad 154 of the semiconductor chips 100A1, 100A2, and 100A3 immediately below. For example, the front pad 152 is connected to the back pad 154, thereby providing an electrical connection path between the semiconductor chips 100A1, 100A2, 100A3, and 100C. The back pad 154 may be arranged on the back (top) of each of the semiconductor chips 100A1, 100A2, and 100A3, and may be connected between the front pad 152 and the through-electrodes 130.

The front (lower surface) and back surface (upper surface) of each of the front pad 152 and the back pad 154 may be polygonal or circular, and the interconnection layer 142 may have a wider width than the line width of the interconnection. Each of the front pad 152 and the back pad 154 may include a metal material that has high conductivity and may be bonded to each other, such as copper (Cu) or a copper alloy. The metal material is not limited to copper, and may be implemented as at least one from among aluminum (Al), nickel (Ni), gold (Au), cobalt (Co), tantalum (Ta), tellurium (Te), titanium (Ti), tungsten (W) or alloys thereof. For example, the front pad 152 and the back pad 154 may be temporarily bonded to make direct contact and then firmly bonded by mutual diffusion of copper through a high-temperature annealing process.

The front insulating layer 162b may surround the front pad 152, and the back insulating layer 164 may surround the back pad 154. The front surfaces (lower surfaces) and back surfaces (upper surfaces) of the front insulating layer 162b and the front pad 152 may each be coplanar, and the front surfaces (lower surfaces) and back surfaces (upper surfaces) of the back insulating layer 164 (or a second insulating layer 164b thereof) and the back pad 154 may each be coplanar.

Each of the front insulating layer 162b and the back insulating layer 164 may include SiO₂. When the front insulating layer 162b and the back insulating layer 164 are bonded to each other, the oxygen of SiO₂ may form a covalent bond to silicon. Accordingly, the front insulating layer 162b and the back insulating layer 164 may have strong bonding strength. And the insulating material forming the front insulating layer 162b and the back insulating layer 164 is not limited to silicon oxide, and may be implemented with at least one from among SiN, SiCN, and tetraethyloxysilane (TEOS).

For example, the back insulating layer 164 may include a first insulating layer 164a and a second insulating layer 164b (also referred to as a first insulating film and a second insulating film, respectively). The first insulating layer 164a may prevent unwanted electrical connection between the back pad 154 and the semiconductor substrate 110. Additionally, the back pad 154 may be buried in the second insulating layer 164b such that the back surface thereof (upper surface) is exposed. The exposed back surface (upper surface) of the back pad 154 may have a back surface (upper surface) that is substantially flat with the back surface (upper surface) of the second insulating layer 164b. In some embodiments, the first insulating layer 164a and the second insulating layer 164b may be formed of the same material, but are not limited thereto and may be formed of different materials. For example, the first insulating layer 164a may include silicon nitride or silicon oxynitride, and the second insulating layer 164b may include silicon oxide.

A plurality of semiconductor chips (e.g., the semiconductor chips 100A1, 100A2, 100A3, and 100C) may be bonded to each other through direct bonding DB2 between the front insulating layer 162b and the back insulating layer 164. Additionally, the plurality of semiconductor chips (e.g., the semiconductor chips 100A1, 100A2, 100A3, and 100C) may be electrically connected to each other through direct bonding DB1 between the front pad 152 and the back pad 154. Direct bonding DB1 may be intermetallic bonding, and direct bonding DB2 may be inter-dielectric bonding. A combination of direct bonding DB1 and direct bonding DB2 may be hybrid bonding.

Due to at least one of the direct bonding DB1 and direct bonding DB2, a conductive structure with a relatively low melting point, such as a bump or solder, may not be disposed between the plurality of semiconductor chips (e.g., the semiconductor chips 100A1, 100A2, 100A3, and 100C). Generally, the conductive structures (e.g., bumps, solder) may be formed through a reflow process or a thermal compression bonding (TCB) process. A minimum width or pitch may be required to ensure reliability.

Due to at least one from among the direct bonding DB1 and the direct bonding DB2, since a plurality of semiconductor chips (e.g., the semiconductor chips 100A1, 100A2, 100A3, and 100C) may be bonded to each other without using the conductive structure (e.g., bump, solder), it may be advantageous to reduce the width or pitch of each of the front pad 152 and the back pad 154. Accordingly, the plurality of semiconductor chips (e.g., the semiconductor chips 100A1, 100A2, 100A3, and 100C) may efficiently increase the integration of the front pad 152 and the back pad 154. The higher the integration of the front pad 152 and the back pad 154, the more the integration of electrical paths (e.g., paths through which at least one of a data signal, a control signal, a power signal, and a ground signal passes) of the plurality of semiconductor chips (e.g., the semiconductor chips 100A1, 100A2, 100A3, and 100C) may also be increased. Accordingly, the semiconductor package 500 may be more advantageous for miniaturization and high performance. Alternatively, due to at least one from among the direct bonding DB1 and the direct bonding DB2, electrical reliability (e.g., impedance stability, equivalent series resistance reduction, signal integrity, power integrity, etc.) between the front pad 152 and the back pad 154 may be further improved.

Due to at least one from among the direct bonding DB1 and the direct bonding DB2, since the front surface and back surface of a plurality of semiconductor chips (e.g., the semiconductor chips 100A1, 100A2, 100A3, and 100C) may be in direct contact with each other, front and back leveling may become more important. The higher the flatness of the front and back, reliability of the front pad 152 and back pad 154 (e.g., performance to prevent poor contact or electrical shorts) and reliability of the front insulating layer 162b and back insulating layer 164 (e.g., performance to prevent pores or cracks) may be improved.

The conductive pattern 147 may be disposed between the interconnection structure 140 and the front pad 152. The support insulating layer 162a may be disposed between the device layer 120 and the front insulating layer 162b to surround the conductive pattern 147. The front surfaces (lower surfaces) and back surfaces (upper surfaces) of the conductive pattern 147 and the support insulating layer 162a may respectively be coplanar.

When the front pad 152 is coupled to the back pad 154 through an annealing process, not only the front pad 152 but also the conductive pattern 147 may be thermally expanded. Thermal expansion of the conductive pattern 147 may support thermal expansion of the back pad 154 and the front pad 152. Accordingly, the front pad 152 and the back pad 154 may be more efficiently coupled to each other. The higher the coupling efficiency between the front pad 152 and the back pad 154, the smaller the minimum volume required for the front pad 152 and the back pad 154 may be. Accordingly, the width or pitch of the front pad 152 and the back pad 154 may be further refined, and the integration of the electrical paths of the plurality of semiconductor chips (e.g., the semiconductor chips 100A1, 100A2, 100A3, and 100C) may also be further increased.

The support insulating layer 162a may be implemented in the same manner as the front insulating layer 162b. For example, the support insulating layer 162a may include at least one from among SiO₂, SiN, SiCN, and tetraethyloxysilane (TEOS). The conductive pattern 147 may be implemented in the same manner (e.g., same material, same process) as the interconnection layer 142 of the interconnection structure 140. Accordingly, the conductive pattern 147 may be the lowermost interconnection layer of the interconnection structure 140. For example, the conductive pattern 147 may include at least one from among copper, a copper alloy, aluminum, and an aluminum alloy.

The conductive pattern 147 may have a thickness greater than the thickness of each of the plurality of interconnection layers 142. Since the conductive pattern 147 may have a thickness greater than the thickness of each of the plurality of interconnection layers 142, and the conductive pattern 147 may have a relatively large volume. The larger the volume of the conductive pattern 147, the better the thermal expansion of the front pad 152 against the back pad 154 may be supported.

According to some embodiments of the present disclosure, the conductive pattern 147 may include a conductive material (e.g., aluminum) having a higher thermal expansion coefficient than that of the conductive material (e.g., copper) of the front pad 152. Since the thermal expansion coefficient of aluminum is higher than the thermal expansion coefficient of copper, the conductive pattern 147 containing aluminum may more efficiently support the thermal expansion of the front pad 152 containing copper.

The efficiency with which the conductive pattern 147 supports the thermal expansion bond between the front pad 152 and the back pad 154 may be a trade-off with the flatness (or importance of flatness) of the front surface of the plurality of semiconductor chips (e.g., the semiconductor chips 100A1, 100A2, 100A3, and 100C). The semiconductor package 500 and a manufacturing method thereof, according to an example embodiment, may secure one of the thermal expansion bond support efficiency and flatness (or the importance of flatness) while improving the other.

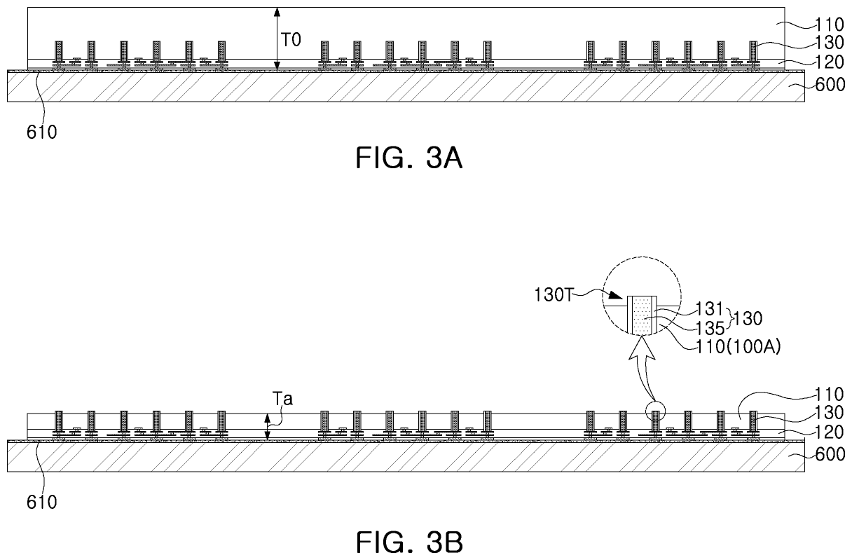

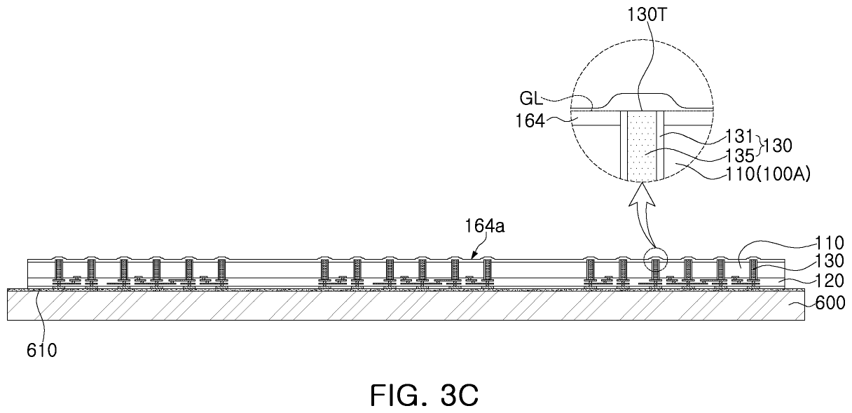

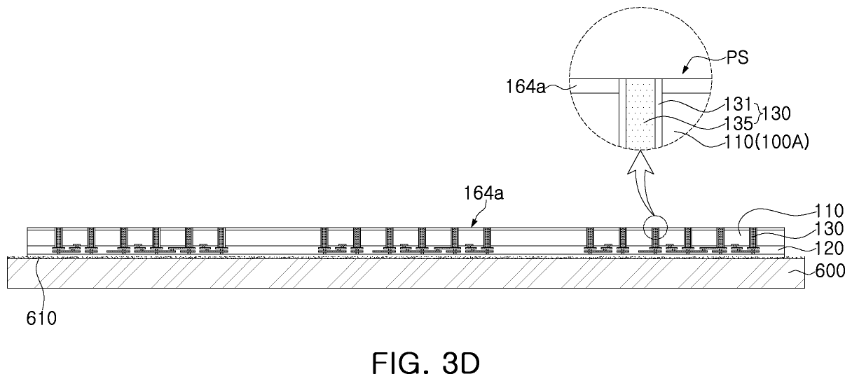

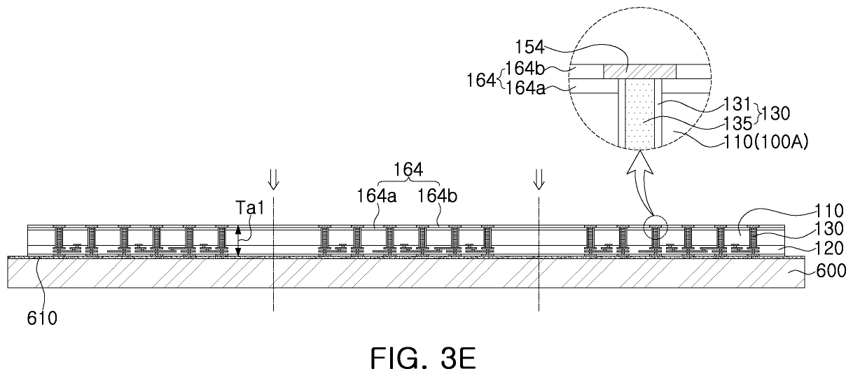

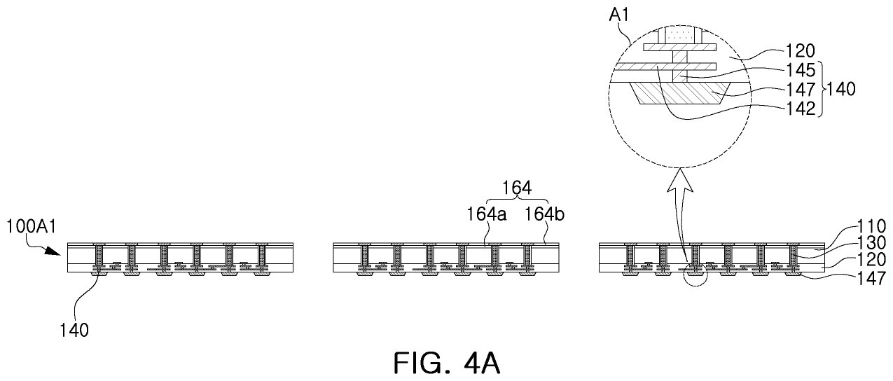

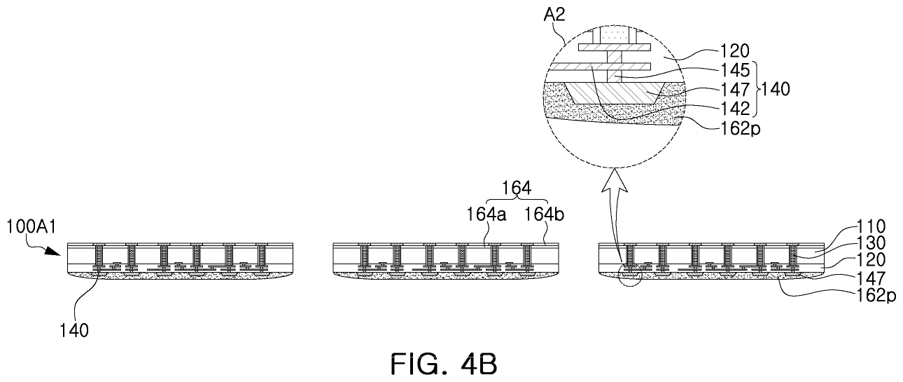

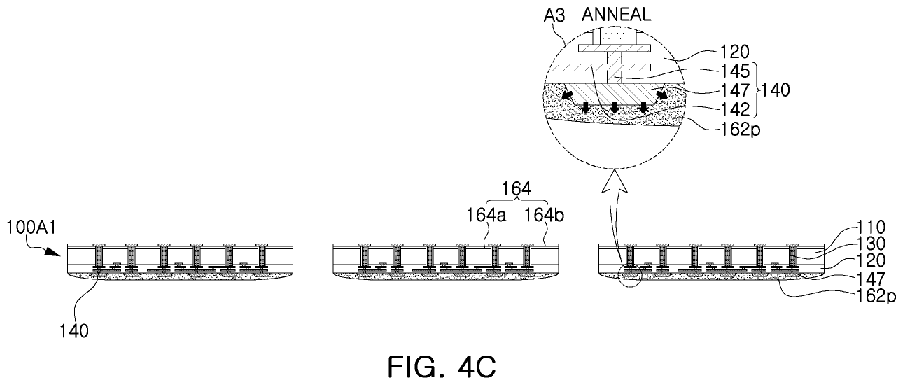

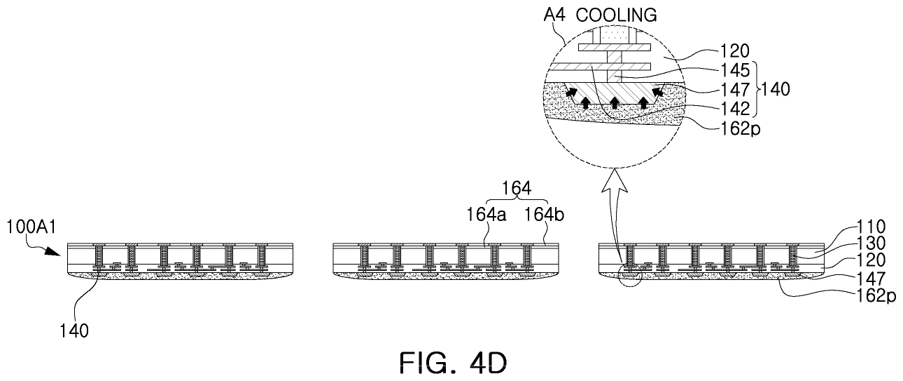

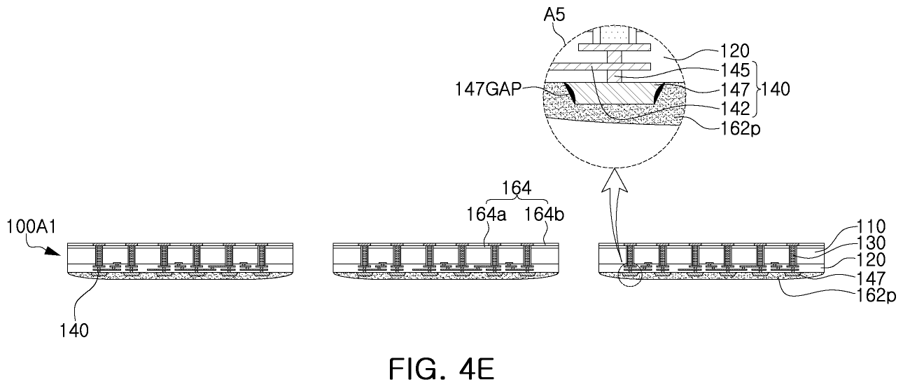

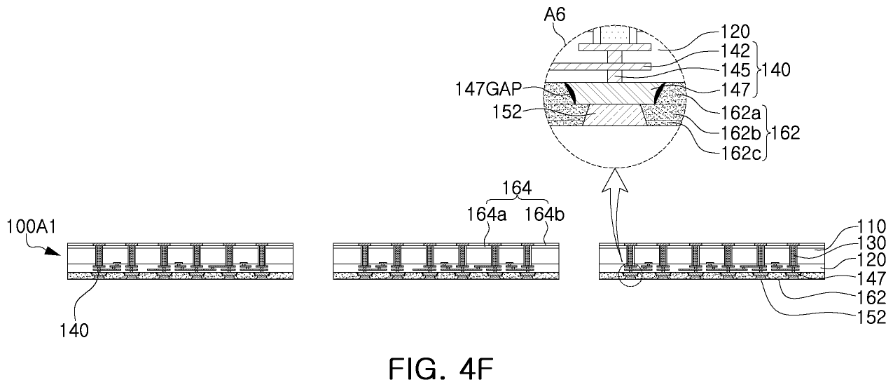

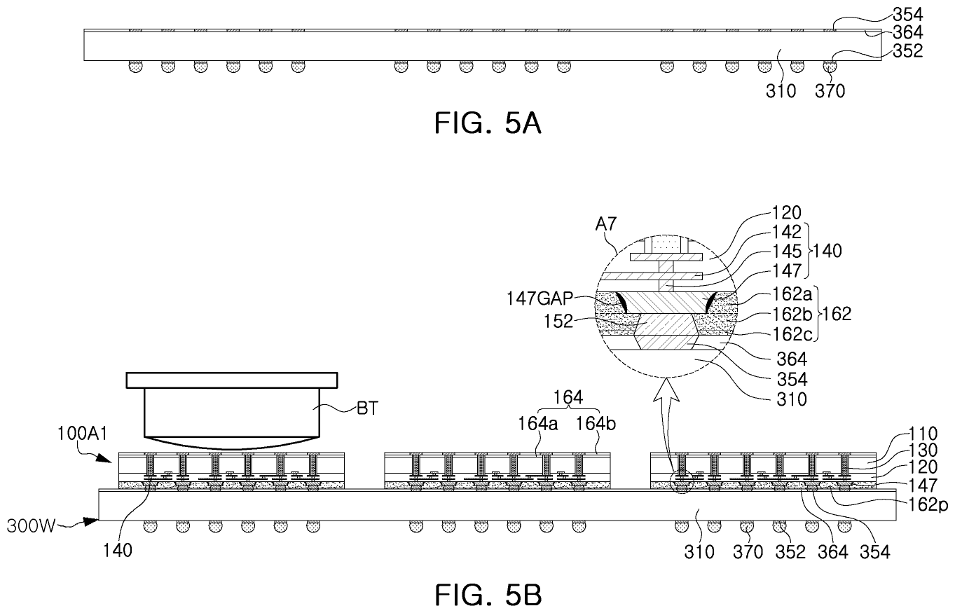

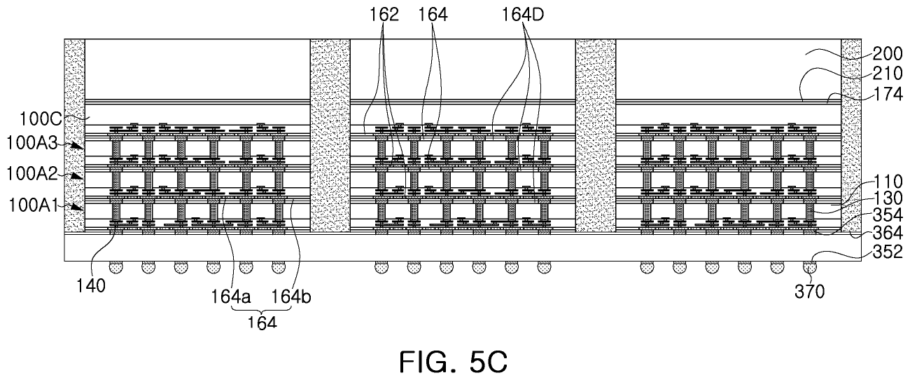

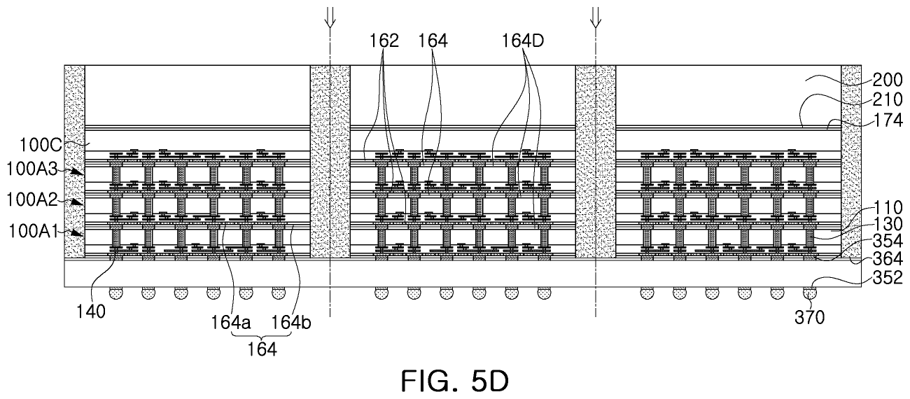

The structure of the semiconductor package according to a method of manufacturing a semiconductor package according to an example embodiment may be formed sequentially from the structure of FIG. 3A to the structure of FIG. 5D. The enlarged regions A1, A2, A3, A4, A5, A6, and A7 of FIGS. 4A to 4F and 5B may correspond to area A of FIG. 1.

Referring to FIG. 4A, a method of manufacturing a semiconductor package according to an example embodiment may include forming a conductive pattern 147 on the front surface (lower surface) of the device layer 120 of at least one of the plurality of semiconductor chips (e.g., semiconductor chip 100A1). Referring to FIG. 4B, the method of manufacturing a semiconductor package may include disposing an insulating material 162p on the front (lower surface) of the device layer 120. Referring to FIG. 4C, the method of manufacturing a semiconductor package may include the operation of annealing the combination of the conductive pattern 147 and the insulating material 162p. Referring to FIG. 4D, the method of manufacturing a semiconductor package may include an operation of cooling the combination of the conductive pattern 147 and the insulating material 162p. Referring to FIGS. 4E and 4F, the method of manufacturing a semiconductor package may include flattening the insulating material 162p to form a support insulating layer 162a, and forming a front pad 152, a front insulating layer 162b, and a front insulating layer 162c on the front surface of the conductive pattern 147 and the support insulating layer 162a. For example, the front insulating layer 162b may include SiO₂, and the front insulating layer 162c may include at least one from among SiN, SiCN, and tetraethyloxysilane (TEOS), and the front insulating layer 162c may be omitted depending on the embodiment. According to embodiments of the present disclosure, a combination of the front insulating layer 162b and the front insulating layer 162c may be collectively called a front insulating layer.

Referring to FIGS. 5A to 5D, the method of manufacturing a semiconductor package may include a direct bonding operation between the front insulating layer (e.g., the front insulating layer 162b, the front insulating layer 162c) of one of the plurality of semiconductor chips (e.g., the semiconductor chips 100A1, 100A2, 100A3 and 100C) and the back insulating layer 164 of another of the plurality of semiconductor chips (e.g., the semiconductor chips 100A1, 100A2, 100A3 and 100C).

Referring to FIGS. 4C to 4F, between the annealing and cooling operations and the operations of forming the front pad 152 and the front insulating layers (e.g., the front insulating layer 162b and the front insulating layer 162c), the gap 147GAP may be formed between side surfaces of the support insulating layer 162a and the conductive pattern 147 facing each other. The cooling operation may lower the ambient temperature of the combination of the conductive pattern 147 and the insulating material 162p to the temperature before the ANNEAL operation.

Referring again to FIGS. 1 to 2B, the semiconductor package 500 according to an example embodiment may include a gap 147GAP located between the side surfaces of the support insulating layer 162a and the conductive pattern 147 facing each other. Accordingly, when the front pad 152 is thermally expanded and coupled to the back pad 154, the component that thermally expands toward the upper edge of the conductive pattern 147 may instead expand into the gap 147GAP. During this time, the efficiency with which the conductive pattern 147 supports thermal expansion of the front pad 152 may have little effect. Accordingly, the influence of thermal expansion of the conductive pattern 147 on the flatness of the front surface of the plurality of semiconductor chips (e.g., the semiconductor chips 100A1, 100A2, 100A3, and 100C) may be reduced, and thermal expansion support efficiency of the front pad 152 may also be secured.

Referring to FIGS. 4B to 4D, the annealing and cooling operations may include annealing and cooling the structure in which the insulating material 162p covers the side and front surfaces (lower surfaces) of the conductive pattern 147. Since the insulating material 162p may be relatively less fluid in a cooling state, in the cooling state, the lateral shape of the insulating material 162p may be relatively less adapted to the change in the lateral shape of the conductive pattern 147 (contraction of the conductive pattern 147). Accordingly, a gap 147GAP may be formed. Depending on the embodiment, the front (lower) surface of the insulating material 162p may be flattened prior to annealing and cooling.

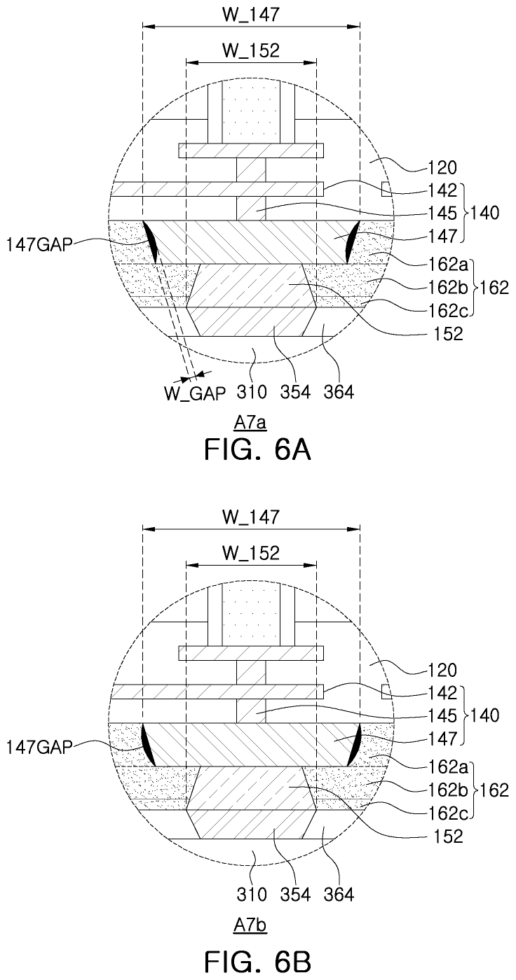

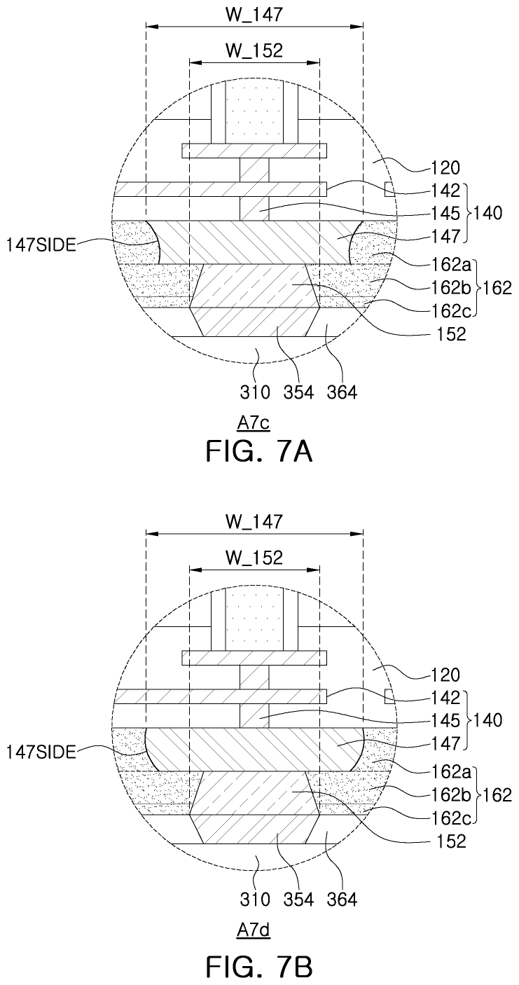

Enlarged regions A7a, A7b, A7c, and A7d of FIGS. 6A to 7B may correspond to the enlarged region A7 of FIG. 5B. Referring to FIG. 6A, the gap 147GAP may have a convex shape toward the conductive pattern 147. Referring to FIG. 6B, the gap 147GAP may have a convex shape toward the support insulating layer 162a. For example, the shape of the gap 147GAP may vary depending on the specific process method (e.g., facility characteristics, annealing atmosphere, temperature, etc.) or the specific material of the support insulating layer 162a. The annealing temperature and time may be the same as the temperature and time for direct bonding described above, but are not limited thereto. This is because annealing temperature and time may affect the size of the gap 147GAP and an optimal size of the gap 147GAP is not limited. For example, the shape of the gap 147GAP may be implemented with multiple pores. In this case, the gap 147GAP may include a structure in which the density of the support insulating layer 162a is lowered in the gap 147GAP. The number of gaps 147GAP is also not limited to 1.

Referring to FIG. 6A, whether a gap 147GAP exists may correspond to whether the thickness W_GAP of the gap 147GAP is longer than the distance (including 0) between the side surfaces of the front insulating layers 162b and 162c and the front pad 152 facing each other. Therefore, when the thickness W_GAP of the gap 147GAP is longer than the distance between the side surfaces of the front insulating layers 162b and 162c and the front pad 152 facing each other (when in contact, the distance is 0), it can be seen that a gap 147GAP exists. In this case, the distance and thickness W_GAP may be measured as the average distance and average thickness, respectively.

Referring to FIGS. 7A and 7B, depending on the specific process method (e.g., facility characteristics, annealing atmosphere, temperature, etc.) or the specific material of the support insulating layer 162a, the gap 147GAP may be replaced by a curved side 147SIDE. For example, at least one of the side surfaces where the support insulating layer 162a and the conductive pattern 147 face each other may be more curved than each of the side surfaces on which the front insulating layers 162b and 162c and the front pad 152 face each other. The curvedness may correspond to the size of the area surrounded by the straight line and curved side 147SIDE extending from the edge of the front (lower surface) to the edge of the back surface (upper surface) of the support insulating layer 162a. Accordingly, a measurement of the curved side 147SIDE may be a measurement of the size. The curved side 147SIDE may be formed based on a structure in which the density of the support insulating layer 162a is lowered at the curved side 147SIDE. Accordingly, the measurement of the curved side 147SIDE may be based on the measurement of the density.

Referring to FIGS. 1 and 2A, the conductive pattern 147 may include a pad pattern 147a electrically connected between the interconnection structure 140 and the front pad 152, and dummy patterns 147b and 147c spaced apart from the front pad 152 and the pad pattern 147a.

For example, the front (lower) and back (upper) surfaces of the pad pattern 147a may be polygonal or circular. Referring to FIGS. 2A and 6A, the width W_147 of the pad pattern 147a may be wider than the width W_152 of the front pad 152. Accordingly, the pad pattern 147a may support the front pad 152 more stably.

Referring to FIGS. 2A and 6A, a portion (e.g., central region) of the front surface (lower surface) of the pad pattern 147a is in direct contact with the front pad 152, and another part (e.g., edge area) of the front (lower surface) of the pad pattern 147a may directly contact the front insulating layer 162b. Accordingly, the overall stacking stability of the combination of the support insulating layer 162a and the front insulating layer 162b may be improved, and delamination of the combination may be reliably prevented.

The dummy patterns 147b and 147c may be filled in most of the spaces surrounding the pad pattern 147a to prevent the metal material from concentrating at specific points in the combination of the conductive pattern 147 and the support insulating layer 162a. Accordingly, even if the conductive pattern 147 is thicker than the interconnection layer 142, the combination of the conductive pattern 147 and the support insulating layer 162a may be stably stacked on the front (lower surface) of the device layer 120, and the occurrence of delamination of the above combination may be reliably prevented.

The dummy patterns 147b and 147c may be electrically connected to power or ground. Since the dummy patterns 147b and 147c may surround the pad pattern 147a, the pad pattern 147a may be electromagnetically shielded. Additionally, the relatively large volume of the dummy patterns 147b and 147c may improve the electrical stability of the power source or ground.

On the other hand, referring to FIG. 1, the semiconductor package 500 according to an example embodiment may include an upper dummy chip 200 disposed on the back surface (upper surface) of the semiconductor chip 100C. For example, the upper dummy chip 200 may include a semiconductor such as silicon or a metal substrate. In some embodiments, the upper dummy chip 200 may provide a heat dissipation function and/or an identification mark display area.

The upper dummy chip 200 may have a thickness T2 greater than a thickness T1a of the semiconductor chips 100A1, 100A2, and 100A3 and a thickness T1b of the semiconductor chip 100C. For example, the thickness T2 of the upper dummy chip 200 may be 200 μm or more, and the thickness T1a and the thickness T1b) may be 100 μm or less.

A lower bonding insulating layer 210 may disposed on a lower surface of the upper dummy chip 200, and a back insulating layer 174 may be disposed on an upper surface of the semiconductor chip 100C. The upper dummy chip 200 may be bonded to the back (upper surface) of the semiconductor chip 100C by directly bonding the lower bonding insulating layer 210 and the back insulating layer 174. In this manner, the upper dummy chip 200 and the semiconductor chip 100C may be bonded by inter-dielectric bonding of the lower bonding insulating layer 210 and the back insulating layer 174. At least one from among the lower bonding insulating layer 210 and the back insulating layer 174 may include a dielectric layer formed by a deposition process. In contrast, it may include a natural oxide film formed during a high temperature annealing process.

The width W2 (or area) of the upper dummy chip 200 may be equal to the width W1a (or area) of the semiconductor chips 100A1, 100A2, and 100A3, and may be the same as the width W1b (or area) of the semiconductor chip 100C, but is not limited thereto.

Referring to FIG. 1, a semiconductor package 500 according to an example embodiment may include a molding part 180 that seals the plurality of semiconductor chips (e.g., the semiconductor chips 100A1, 100A2, 100A3, and 100C) and the upper dummy chip 200. For example, the molding part 180 may include epoxy mold compound (EMC), etc.

An upper surface 200T of the upper dummy chip 200 is exposed by the upper surface 180T of the molding part 180. The upper surface 200T of the upper dummy chip 200, that is exposed, may have a substantially flat coplanar surface with the upper surface 180T of the molding part 180. These coplanar upper surfaces may be understood as upper surfaces obtained through a polishing process. Additionally, the side surface of the molding part 180 may have a substantially flat coplanar surface with the side surface of the base structure 300. These coplanar side surfaces may be understood as side surfaces obtained by the same cutting process.

Referring to FIG. 1, a semiconductor package 500 according to an example embodiment may include a base structure 300 disposed below the plurality of semiconductor chips (e.g., the semiconductor chips 100A1, 100A2, 100A3, and 100C). The base structure 300 may include lower connection pads 352 disposed on a lower surface of the base structure 300 and upper connection pads 364 disposed on an upper surface of the base structure 300.

In this embodiment, the base structure 300 may have a width (or area) greater than the widths W1a and W1b (or area) of the plurality of semiconductor chips (e.g., the semiconductor chips 100A1, 100A2, 100A3 and 100C). The lowermost semiconductor chip (e.g., the semiconductor chip 100A1) among the plurality of semiconductor chips (e.g., the semiconductor chips 100A1, 100A2, and 100A3) may be directly bonded to the base structure 300, similar to the direct bonding DB1 and the direct bonding DB2 described above.

In detail, the front pads 152 of the semiconductor chip 100A1 adjacent to the base structure 300 may be directly bonded to the upper connection pads 354 to form direct bonding DB1. This direct bonding DB1 may bond the base structure 300 and the semiconductor chip 100A1 to each other and ensure an electrical connection. An upper bonding insulating layer 364 is formed on the upper surface of the base structure 300 employed in this embodiment, and the upper bonding insulating layer 364 may have a substantially flat upper surface that is coplanar with upper surfaces the upper connection pads 354. The upper bonding insulating layer 364 of the base structure 300 and the front insulating layer 162 of the lowermost semiconductor chip 100A1 may be directly bonded to form direct bonding DB2. In this manner, the base structure 300 and the lowermost semiconductor chip 100A1 may be hybrid bonded.

For example, the base structure 300 may be an interposer for redistribution. The base structure 300 may include a substrate body 310 and an interconnection circuit connecting the lower connection pads 352 and the upper connection pads 354 within the substrate body 310. Connection bumps 370 may be attached to the lower connection pads 352 of the base structure 300. The connection bump 370 may be, for example, a solder ball or a conductive bump. The connection bump 370 may be electrically connected to the semiconductor package 500 and a printed circuit board such as a motherboard. In some embodiments, the base structure 300 may include a semiconductor chip.

Referring to FIGS. 3A to 3E, a method of manufacturing a semiconductor package according to an example embodiment includes may include forming a device layer 120, a semiconductor substrate 110, a back insulating layer 164, and a back pad 154.

Referring to FIG. 3A, a semiconductor substrate 110 for a plurality of semiconductor chips 100A is bonded to the carrier substrate 600. For convenience of description, the semiconductor substrate 110 is illustrated as a wafer including three semiconductor chips 100A. A plurality of individual semiconductor chips may be formed on the active surface of the semiconductor substrate 110. Additionally, through-electrodes 130 may extend into the semiconductor substrate 110, and a device layer 120 may be connected to the through-electrodes 130 and formed on the active surface of the semiconductor substrate 110. In this manner, the semiconductor substrate 110 may be understood as being in a state in which the back surface process has not been performed after completing the front process of the semiconductor chip. For example, since the semiconductor substrate 110 has not been subjected to a grinding process, the semiconductor substrate 110 may have a relatively large first thickness T0. The front surface (lower surface) of the semiconductor substrate 110, for example, the side on which the device layer is formed, is bonded to face the carrier substrate 600. This bonding may be implemented by an adhesive layer 610, such as a, ultra-violet (UV) curable film.

Referring to FIG. 3B, a grinding process is applied to the inactive surface of the semiconductor substrate 110 so that the first thickness T0 of the semiconductor substrate 110 is reduced to a thickness Ta. In this grinding, the top 130T of the through-electrode 130 may be exposed from the ground surface of the semiconductor wafer. Due to differences in etching rates, the semiconductor wafer 100 may protrude from the surface. Through this process, the thickness of the semiconductor chip 100A may be reduced to the thickness Ta (a desired thickness). This thickness reduction process may be performed by an etch-back process or a combination thereof in addition to a grinding process such as a chemical mechanical polishing (CMP) process. In some embodiments, a grinding process is performed to reduce the thickness of the semiconductor substrate 110, and by applying etch-back under appropriate conditions, the through-electrode 130 may be sufficiently exposed.

Referring to FIG. 3C, a first insulating layer 164a may be formed on the semiconductor substrate 110 to cover the top 130T of the through-electrode 130 that is exposed. The first insulating layer 164a may be used as a passivation layer. For example, the first insulating layer 164a may include silicon nitride or silicon oxynitride.

Referring to FIG. 3D, the first insulating layer 164a may be ground to expose the through-electrode 130. A grinding process may be performed up to a predetermined line GL (refer to FIG. 3C) so that the first insulating layer 164a is partially removed and the through-electrode 130 is sufficiently exposed. By this grinding process, the first insulating layer 164a may have a upper surface that is substantially flat and coplanar with the upper surface of the through-electrode 130. Additionally, the damaged portion of the top 130T of the through-electrode 130 may also be removed.

Referring to FIG. 3E, back pads 154 and a second insulating layer 164b surrounding the back pads 154 may be formed on the first insulating layer 164a. Similar to the previous processes, back pads 154 are formed on the first insulating layer 164a, a second insulating layer 164b is formed to cover the back pads 154. Next, a grinding process may be performed so that the second insulating layer 164b is partially removed to expose the back (upper) surfaces of the back pads 154. Through this grinding process, the second insulating layer 164b may have a back surface (upper surface) that is substantially flat and coplanar with the back surfaces (upper surfaces) of the back pads 154. For example, the second insulating layer 164b may include silicon oxide. In this specification, the first insulating film 164a and the second insulating layer 164b are collectively referred to as the back insulating layer 164.

FIGS. 3A to 4A illustrate that the conductive pattern 147 is formed after the semiconductor substrate 110, the back insulating layer 164, and the back pad 154 are formed. Depending on the embodiment, the conductive pattern 147 may be formed together with the device layer 120. This is because the conductive pattern 147 may be a portion of the interconnection structure 140 of the device layer 120. For example, the operation of forming the conductive pattern 147 on the front (lower) surface of the device layer 120 of at least one of the plurality of semiconductor chips (e.g., the semiconductor chip 100A) may be a portion of the operation of forming the device layer 120. Likewise, the operations illustrated in FIGS. 4B to 4F may also be performed before the semiconductor substrate 110, the back insulating layer 164, and the back pad 154 are formed, depending on the embodiment.

Referring to FIG. 5A, a base structure 300W having upper connection pads 354 and lower connection pads 352 is prepared. For convenience of descriptions, the base structure 300W is illustrated in a form for manufacturing three semiconductor packages. An upper bonding insulating layer 364 surrounding the upper connection pads 354 may be provided on an upper surface of the base structure 300W. The upper bonding insulating layer 364 may have an upper surface that is substantially flat and coplanar with the upper surfaces of the upper connection pads 354. Connection bumps 370, such as solder balls, may be formed on the lower connection pads 352 of the base structure 300W. Additionally, in this embodiment, the base structure 300W is illustrated as an interposer having an internal circuit that electrically connects the upper connection pads 354 and the lower connection pads 352. In contrast, the base structure 300W may be implemented as a logic chip or a memory chip.

Referring to FIG. 5B, individualized semiconductor chips 100A1 are placed on the base structure 300W. The semiconductor chip 100A1 may be a semiconductor chip obtained in the operation illustrated in FIG. 4F. This lamination process may be temporarily bonded by applying a certain pressure using a bonding tool BT. In detail, the front pads 152 of the semiconductor chips 100A1 are each directly pre-bonded to the upper connection pads 354 of the base structure 300, and similarly, the front insulating layer 162 of the semiconductor chips 100A1 may be directly temporarily bonded to the upper bonding insulating layer 364 of the base structure 300.

Referring to FIG. 5C, additional semiconductor chips 100A2 and 100A3 are sequentially stacked, and the semiconductor chip 100C is placed on the top semiconductor chips (e.g., the semiconductor chips 100A3). The plurality of semiconductor chips 100A2, 100A3, and 100C may be temporarily bonded to other semiconductor chips 100A1, 100A2, and 100A3 located below them. In detail, the front pads 152 and front insulating layer 162 of each of the semiconductor chips 100A2, 100A3, 100C may be directly temporarily bonded to the back pads 154 and the back insulating layer 164 of the semiconductor chips 100A1, 100A2, and 100A3 stacked immediately before, respectively. Afterwards, the annealing process may proceed, and the front insulating layer 162 and the back insulating layer 164 may be directly bonded, and the front pads 152 and the back pads 154 may be directly bonded. Thereafter, the upper dummy chip 200 may be placed on the back surface (upper surface) of the semiconductor chip 100C, and the back surface (upper surface) of the upper dummy chip 200 may be polished.

Referring to FIG. 5D, the semiconductor package illustrated in FIG. 5C may be cut in the vertical direction. Accordingly, a plurality of semiconductor packages may be formed. Depending on the embodiment, the back surface (upper surface) of the upper dummy chip 200 may include an identification mark or provide a space for placing a heat sink.

As set forth above, in a semiconductor package and a method of manufacturing a semiconductor package according to example embodiments, electrical characteristics and/or reliability of a front surface of a semiconductor chip may be improved.

While example embodiments have been illustrated and described above, it will be apparent to those skilled in the art that modifications and variations could be made without departing from the scope of the present disclosure.

What is claimed is:

1. A semiconductor package comprising:
a plurality of semiconductor chips bonded to each other through direct bonding, the plurality of semiconductor chips comprising a first semiconductor chip and a second semiconductor chip,
wherein the first semiconductor chip comprises:
a front insulating layer bonded to a back insulating layer of the second semiconductor chip;
a front pad surrounded by the front insulating layer;
a device layer on a back surface of the front insulating layer and comprising an interconnection structure electrically connected to the front pad;
a conductive pattern between the interconnection structure and the front pad; and
a support insulating layer between the device layer and the front insulating layer and surrounding the conductive pattern,
wherein a gap is between a first side surface of the support insulating layer and a second side surface of the conductive pattern that faces the first side surface.

2. The semiconductor package of claim 1, wherein the conductive pattern comprises a pad pattern electrically connecting the interconnection structure to the front pad.

3. The semiconductor package of claim 2, wherein the conductive pattern further comprises a dummy pattern spaced apart from the front pad and the pad pattern.

4. The semiconductor package of claim 2, wherein a portion of a front surface of the pad pattern is in direct contact with the front pad, and
wherein another portion of the front surface of the pad pattern is in direct contact with the front insulating layer.

5. The semiconductor package of claim 2, wherein a width of the pad pattern is larger than a width of the front pad.

6. The semiconductor package of claim 1, wherein the interconnection structure comprises at least one interconnection layer and an interconnection via, and a thickness of the conductive pattern is greater than a thickness of each of the at least one interconnection layer.

7. The semiconductor package of claim 1, wherein the conductive pattern comprises a conductive material having a thermal expansion coefficient higher than a thermal expansion coefficient of a conductive material of the front pad.

8. The semiconductor package of claim 1, wherein the front pad comprises copper or a copper alloy, and
the conductive pattern comprises at least one from among copper, a copper alloy, aluminum, and an aluminum alloy.

9. The semiconductor package of claim 1, wherein each of the front insulating layer and the support insulating layer comprises at least one from among SiO₂, SiN, SiCN, and tetraethyloxysilane (TEOS).

10. The semiconductor package of claim 1, wherein the second semiconductor chip comprises:
a device layer comprising an interconnection structure;
a semiconductor substrate on a back surface of the device layer of the second semiconductor chip;
a through-electrode penetrating through the semiconductor substrate;
the back insulating layer, the back insulating layer being on a back surface of the semiconductor substrate; and
a back pad surrounded by the back insulating layer and electrically connected to the through-electrode, and
wherein the first semiconductor chip is electrically connected to the second semiconductor chip via direct bonding between the front pad of the first semiconductor chip and the back pad of the second semiconductor chip.

11. The semiconductor package of claim 1, wherein a thickness of the gap is greater than a distance between a third side surface of the front insulating layer and a fourth side surface of the front pad that faces the third side surface.

12. The semiconductor package of claim 1, wherein at least one of the first side surface of the support insulating layer and the second side surface of the conductive pattern that faces the first side surface, is curved more than each of a third side surface of the front insulating layer and a fourth side surface of the front pad that faces the third side surface.

13. A semiconductor package comprising:
a semiconductor chip comprising:
a front insulating layer;
a front pad surrounded by the front insulating layer;
a device layer on a back surface of the front insulating layer and comprising an interconnection structure electrically connected to the front pad;
a conductive pattern between the interconnection structure and the front pad;
a support insulating layer between the device layer and the front insulating layer and surrounding the conductive pattern;
a semiconductor substrate on a back surface of the device layer;
a through-electrode penetrating through the semiconductor substrate; and
a back insulating layer on a back surface of the semiconductor substrate,
wherein at least one from among a first side surface of the support insulating layer and a second side surface of the conductive pattern that faces the first side surface is curved more than each of a third side surface of the front insulating layer and a fourth side surface of the front pad that faces the third side surface.

14. The semiconductor package of claim 13, wherein a gap is between the first side surface of the support insulating layer and the second side surface of the conductive pattern.

15. The semiconductor package of claim 14, wherein a thickness of the gap is greater than a distance between the third side surface of the front insulating layer and the fourth side surface of the front pad.

16. The semiconductor package of claim 13, wherein the conductive pattern further comprises a pad pattern that electrically connects the interconnection structure to the front pad,
a portion of a front surface of the pad pattern is in direct contact with the front pad, and
another portion of the front surface of the pad pattern is in direct contact with the front insulating layer.

17. The semiconductor package of claim 13, wherein the interconnection structure comprises at least one interconnection layer and an interconnection via, and
a thickness of the conductive pattern is greater than a thickness of each of the at least one interconnection layer.

18. The semiconductor package of claim 13, wherein the front pad comprises copper or a copper alloy,
the conductive pattern comprises at least one from among copper, a copper alloy, aluminum, and an aluminum alloy, and
each of the front insulating layer and the support insulating layer comprises at least one from among SiO₂, SiN, SiCN, and tetraethyloxysilane (TEOS).

19. A method of manufacturing a semiconductor package, comprising:
forming a conductive pattern on a front surface of a device layer of a first semiconductor chip;
disposing an insulating material on the front surface of the device layer;
annealing and cooling a combination portion of the conductive pattern and the insulating material;
forming a support insulating layer by flattening the insulating material;
forming a front pad and a front insulating layer on a front surface of the conductive pattern and a front surface of the support insulating layer; and
direct bonding the front insulating layer of the first semiconductor chip to a back insulating layer of a second semiconductor chip.

20. The method of claim 19, wherein the combination portion comprises a structure in which the insulating material covers a side surface and the front surface of the conductive pattern.
